(19) United States
(12) Patent Application Publication
(10) Pub. No.: US 2006/0214278 A1
(43) Pub. Date: Sep. 28, 2006

(54) Shield and semiconductor die assembly

(75) Inventor: Nigel Iain Martin, Salo (FI)

Correspondence Address: HARRINGTON & SMITH, LLP, 4 RESEARCH DRIVE, SHELTON, CT, 06484-6212, US

(73) Assignee: Nokia Corporation

(21) Appl. No.: 11/090,715

(22) Filed: Mar. 24, 2005

(51) Int. Cl. H01L 23/02

(52) U.S. Cl. 257/686

(57) ABSTRACT

An electronic assembly including a substrate; a semiconductor die; and a shield formed around and mounted to the semiconductor die and located, at least partially, between the semiconductor die and the substrate. A method of assembling an electronic assembly includes selecting a first electronic component assembly from a plurality of different electronic component assemblies, the first electronic component assembly including a semiconductor die with an attached shield; and connecting the selected first electronic component assembly to a substrate to form the electronic assembly. The electronic assembly is formed with the shield already attached to the semiconductor die without having to attached the shield to the semiconductor die or substrate after the semiconductor die is attached to the substrate.

### BACKGROUND OF THE INVENTION

1. Field of the Invention

The present invention relates to an electronic assembly and, more particularly, to a shield and semiconductor die assembly.

2. Brief Description of Prior Developments

At present an integrated circuit (IC) is made up of the semiconductor die, the substrate (such as a laminate board) and a molding. Typically an integrated circuit vendor places the die on the laminate and uses bonding wires to connect the die to external pins. The molding (package) is used to cover the die and the substrate. It is well known to shield integrated circuits (IC) by applying a metalized can onto the substrate over the die prior to the IC molding which subsequently covers the die, metalized can and substrate.

U.S. Pat. No. 6,734,539 discloses a method of integrating a shielding into a module. U.S. Pat. No. 6,515,870 discloses a method of integrating a shielding in a module. However, these are based on the use of wire bonding to form the Faraday cage. U.S. patent application Publication No. 2002/0050401 A1 discloses an integrated EMI shield utilizing a hybrid edge.

In the design of mobile terminals, such as a mobile telephone or a mobile communication device, the implementation of the shielding requirements adds significantly to the terminal size and cost. Shielding is routinely implemented by the use of supra-shielding metal cans covering the parts that are most sensitive to radio frequency (RF) interference or those that are most likely to radiate RF signals. Supra-shields are shields that are mounted on top of a motherboard; usually SMD. The metal Supra-shields add to the component count and cost of the terminals. The attachment of the Supra-shields to the motherboard can be unreliable and often there are yield problems.

The height of the Supra-shields is determined by the clearance distance above the components inside, typically the tallest component included in the cavity so formed. The percentage of wasted volume can be large. Typically, there is a large perimeter area needed to solder the Supra-shields. This area is consequently unavailable for routing or component placing. One problem is that shielding design is done for each terminal design. In most situations, every terminal design requires its own specific shielding design and experimentation; often causing delays, extra cost and failures.

There is a desire to integrate a shield within the molding which can remove the need for external shields. However, integrating the shield inside the IC can increase the thickness of the IC. This invention, among other things, outlines how the shield can be embedded within the substrate without increasing the thickness. It also provides a means of allowing IC designers to take a more hands-on approach in designing IC shielding. Also, molding may not be necessary at all, since the die can be embedded directly in an organic laminate.

### SUMMARY OF THE INVENTION

In accordance with one aspect of the present invention, an electronic assembly is provided including a substrate; a semiconductor die; and a shield mounted to the semiconductor die and located, at least partially, between the semiconductor die and the substrate. The die can be inside the substrate and surrounded by the shield, which is part of the laminate.

In accordance with one method of the present invention, a method of assembling an electronic assembly is provided comprising selecting a first electronic component assembly from a plurality of different electronic component assemblies, the first electronic component assembly including a semiconductor die with an attached shield; and connecting the selected first electronic component assembly to a substrate to form the electronic assembly. The electronic assembly is formed with the shield already attached to the semiconductor die without having to attach the shield to the semiconductor die or substrate after the semiconductor die is attached to the substrate.

In accordance with another method of the present invention, a method of assembling an electronic assembly is provided comprising selecting a first electronic component assembly from a plurality of different electronic component assemblies, the first electronic component assembly comprising a semiconductor die with an attached shield; and connecting the selected first electronic component assembly to a substrate to form the electronic assembly. The electronic assembly is formed with the shield already attached to the semiconductor die without having to attach the shield to the semiconductor die or substrate after the semiconductor die is attached to the substrate.

In accordance with another aspect of the present invention, an electronic component assembly is provided comprising a semiconductor die; and a shield fixedly connected to the semiconductor die. The electronic component assembly is sized and shaped to be, at least partially mounted in a receiving area of a substrate with at least a portion of the shield being located between the semiconductor die and the substrate.

### BRIEF DESCRIPTION OF THE DRAWINGS

The foregoing aspects and other features of the present invention are explained in the following description, taken in connection with the accompanying drawings, wherein:

FIG. 1 is a schematic sectional view of an electronic assembly incorporating features of the present invention;

FIGS. 2-6 show steps used to form one embodiment of the present invention;

FIG. 7 is a top plan view of a motherboard comprising features of the present invention;

FIG. 8 is a schematic sectional view of a module incorporating features of the present invention;

FIG. 9 is a schematic sectional view of an alternate embodiment of the present invention;

FIGS. 10-16 show steps used to form an alternative embodiment of the present invention.

### DETAILED DESCRIPTION OF THE PREFERRED EMBODIMENTS

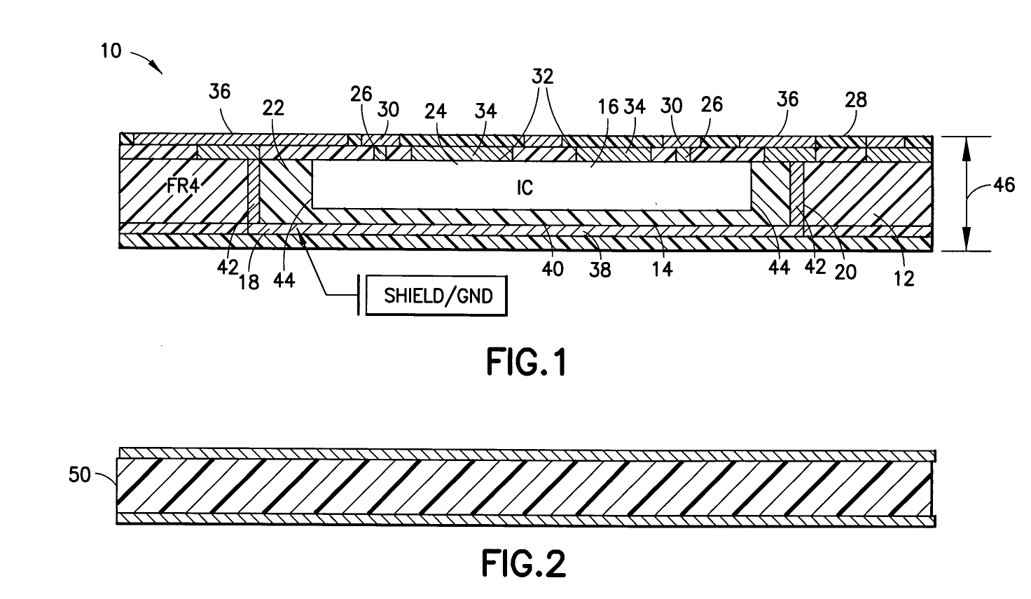

Referring to FIG. 1, there is shown a sectional view of an electronic assembly 10 incorporating features of the present invention. Although the present invention will be described with reference to the exemplary embodiments shown in the drawings, it should be understood that the present invention can be embodied in many alternate forms of embodiments. In addition, any suitable size, shape or type of elements or materials could be used.

In the embodiment shown the electronic assembly 10 comprises a printed circuit board assembly. The assembly 10 comprises a substrate 12 and a subassembly 14. The substrate 12 comprises a laminate board. However, in alternate embodiments other types of substrates could be provided. The subassembly 14 comprises a semiconductor die 16 and a shield 18. The semiconductor die 16 is a conventional semiconductor die well know in the art. The shield 18 comprises metal and forms a Faraday cage for the semiconductor die. An electrical insulator 22 is provided between the shield 18 and the semiconductor die 16.

The semiconductor die 16 has a general block shape with a first side 24 having electrical contact areas 26. In the embodiment shown, the contact areas 26 are connected to conductors 30 at a first side 28 of the assembly 10. Ground contact areas 32 of the semiconductor die 16 are connected to ground conductors 34 of the assembly 10. The ground conductors 34 are coupled to the shield 18 and exterior side contact areas 36.

The shield 18 has a general cross sectional U shape. In particular, the shield has a side 38 located opposite the second side 40 of the die 16 and lateral sides 42 located opposite lateral sides 44 of the die 16. However, in alternate embodiments, the shield could have any suitable shape. Ends of the sides 42 of the shield are coupled to the ground conductors 34 proximate the first side 28 of the of the assembly 10. In this embodiment, the connection between the ground conductors 34 and the ends of the sides 42 is made out of the plane of the cross section shown in FIG. 1, so it is not shown in FIG. 1. The shield 18 and the ground conductors 34 form a Faraday cage around the semiconductor die 16. The Faraday cage can surround the die, with holes to allow the active electrical connections through. The size of these holes can be limited to ensure the effectiveness of the Faraday cage.

The substrate 12, in this embodiment, comprises an aperture 20. The aperture 20 extends entirely through the substrate. However, in an alternate embodiment, the aperture need not extend entirely through the substrate. The subassembly 14 is at least partially mounted in the aperture. More specifically, in this embodiment both the semiconductor die 16 and the shield 18 are located in the aperture. By mounting both the semiconductor die 16 and the shield 18 in the aperture 20, the height 46 of the assembly 10 is smaller than otherwise could be provided if the semiconductor die 16 and shield 18 were mounted on an exterior surface of the substrate 12. In particular, the height of the semiconductor die 16 and shield 18 is substantially co-planar with the height of the substrate 12. Thus, the height of the semiconductor die 16, shield 18 and substrate 12 is substantially no higher than the height of the substrate 12. In an alternate embodiment, the semiconductor die 16 and/or shield 18 could extend above the top surface and/or the opposite bottom surface of the substrate 12 if desired or necessary.

The present invention generally relates to the radio frequency (RF) shielding. In one embodiment, the invention relates to radio frequency (RF) shielding of an embedded component in a mobile terminal. The present invention can also be used to provide a library of embedded, sensitive components or blocks, each with their own associated shield (Faraday cage). The idea is that each component or block of components will have its own directly related and specifically designed shield included in its electronic design library model. Thus, a designer of a mobile terminal, where the components were embedded in the motherboard, would merely select the components or blocks of components with the required functionality and import them directly to the embedded motherboard design; the shielding function being included by default.

The die can be placed internal to the laminate with metal die pad bumps or Ball Grid Array (BGA) pads at the top. Embedding the die within the laminate is a new technique which can be utilized to reduce thickness. The copper area sandwiched between the two and previously utilized for heat dissipation can be utilized for RF shielding. In previous arrangements a metallized can would be placed over both the substrate and the die. This invention can apply to IC's which have the die sitting on the laminate or a die embedded in the laminate.

One main advantage of the present invention is that the thickness of the shielded solution can be lower and the shield arrangement can be specified by IC designers when handing over the die design to an IC vendor. At present it is common for the IC vendor to integrate the shield themselves or products utilize external shields around sensitive areas (e.g. RF IC's).

The idea appears to offer significant advantages in IC design and would be applicable to any IC which is desired to utilize a low profile shielded IC.

Unlike U.S. Pat. No. 6,734,539, the present invention can use embedded shielding. The shield can be immersed or embedded in the substrate; whether the substrate is part of a module or on a motherboard. Unlike U.S. Pat. No. 6,515,870, with the present invention the connection can be made without wire bonding; using rather direct connection of the die pads (copper bumped) to the substrate copper routing.

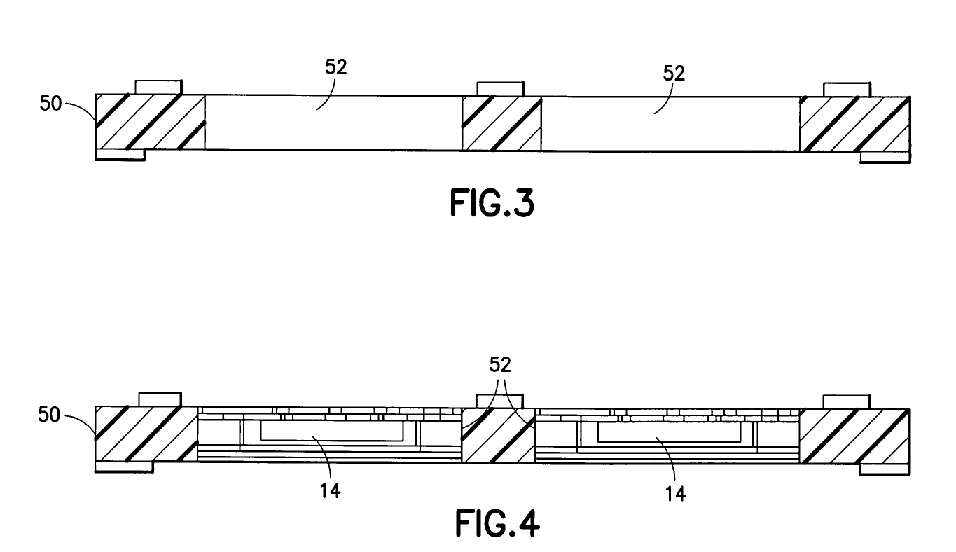

Referring now to FIGS. 2-6, one method of manufacturing an electronic assembly incorporating features of the present invention will be described. As shown in FIGS. 2 and 3, a substrate 50, such as a laminate board, is provided and apertures 52 are formed in the board. Subassemblies 14 are mounted in the apertures 52 as seem in FIG. 4. In an alternate embodiment, the shield 18 could be attached to the substrate before the semiconductor die is connected to the substrate. As seen in FIG. 5, conductors 54 are then formed or attached to the board and connected to contact areas of the semiconductor die and the shield of the subassemblies 14. Fusible elements, such as solder balls 56, can be attached to the conductors as shown in FIG. 6 for subsequently connecting the IC module 58 to another component (not shown). Other components or layers can be added also, such as insulators 55 and conductors 57 for example seen in FIG. 6.

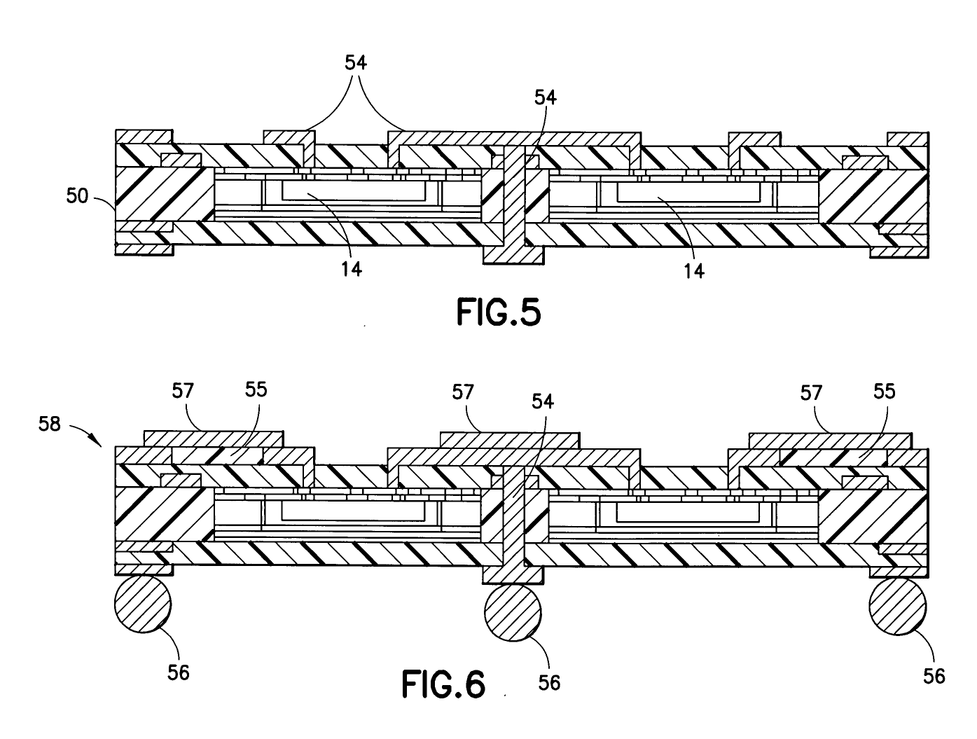

Referring also to FIG. 7, one use of the present invention on a motherboard 60 is shown. The motherboard 60 comprises a substrate 62 with multiple electronic assemblies 14 embedded into apertures of the substrate. The semiconductor dies of the electronic assemblies 14 in the motherboard are different from each other,. In an alternate embodiment one or more of the assemblies 14 could be mounted on the exterior surface of the substrate 62 rather than in an aperture of the substrate. In the embodiment shown, the motherboard is designed for use in a mobile telephone. However, in alternate embodiments, the motherboard could be designed for use in any suitable type of device.

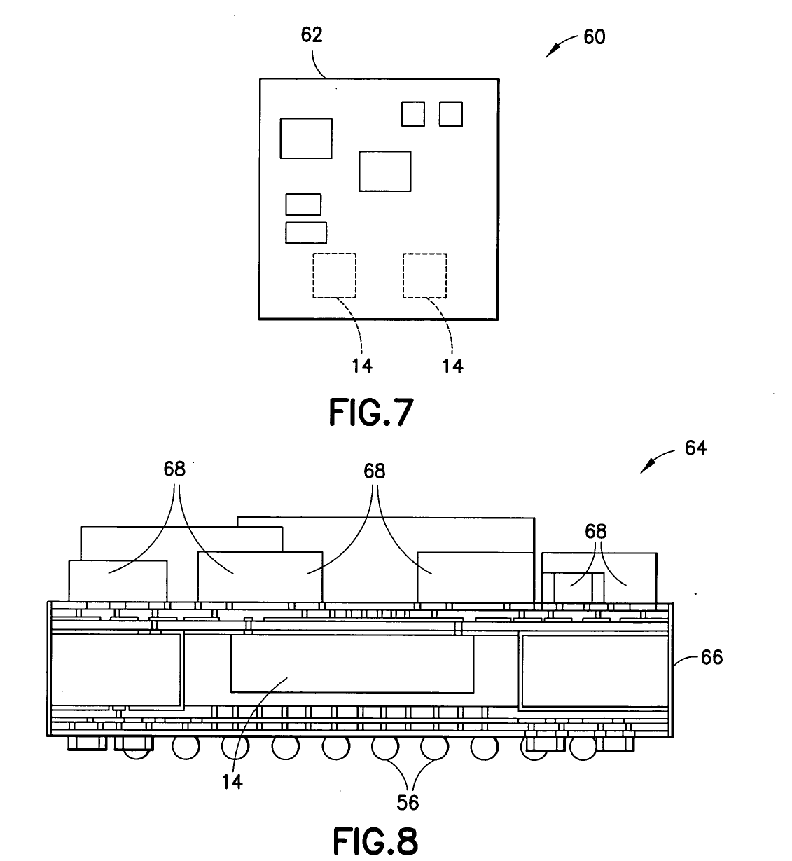

Referring now to FIG. 8, an alternate use of the present invention is shown. In this embodiment the assembly 64 comprises a module adapted to be connected to another component, such as a motherboard for example. The module 64 comprises a substrate 66, a subassembly 14 embedded in an aperture in the substrate, other electronic components 68 attached to a first side of the substrate, and fusible elements 56 attached to conductors at an opposite second side of the substrate. This embodiment illustrates that some of the other electronic components 68 can be placed above the assembly 14. Thus, the footprint of the assembly 64 can be reduced.

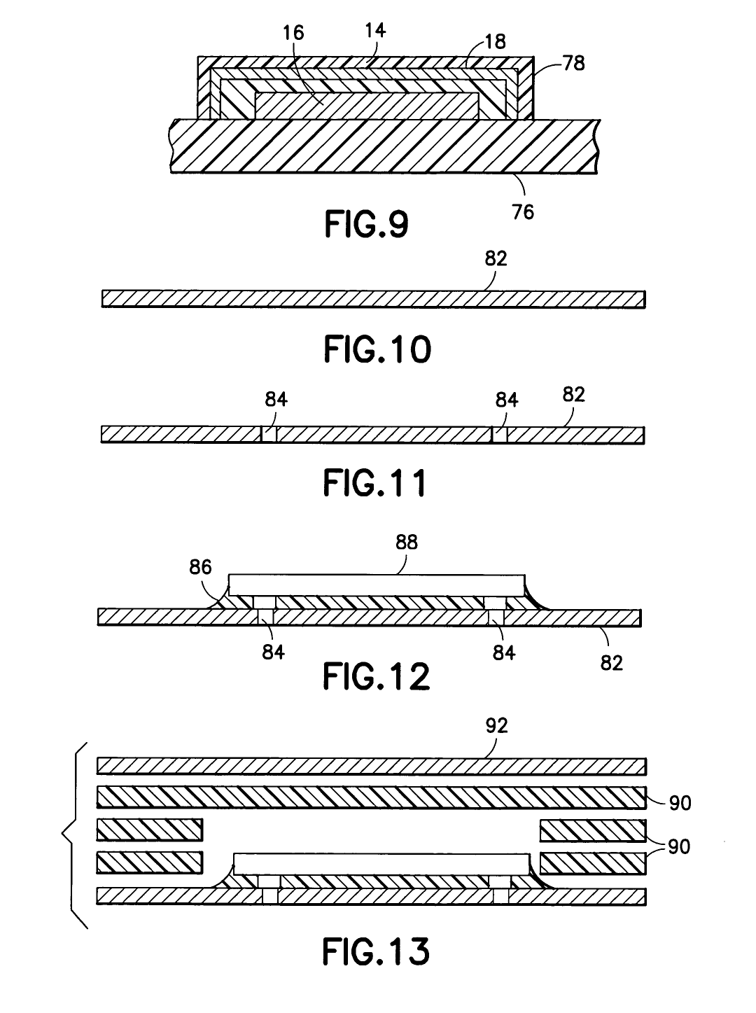

Referring to FIG. 9 an example of use of the assembly 14 on an exterior side of a substrate 76 is shown. The assembly 14 can be provided as a modular component which is attached to the substrate 76 as a one piece unit. Thus, the shield is connected to the semiconductor die before the semiconductor die is connected to the substrate. The electronic assembly 14 is formed with the shield already attached to the semiconductor die without having to attached the shield to the semiconductor die or substrate after the semiconductor die is attached to the substrate. The contact areas of the semiconductor die 16 can be attached to conductors on the substrate 76 and the shield 18 can be attached to ground conductors on the substrate. Thus, the assembly 14 does not need to be embedded inside the substrate. The assembly 14 can comprise a cover 78 such as plastic molded onto the assembly.

One aspect of the present invention proposes a library of embedded, sensitive components or blocks, each with their own associated shield (Faraday cage). The idea is that each component or block of components will have its own directly related and specifically designed shield included in its electronic design library model.

A designer of a terminal, where the components were embedded in the motherboard, would merely select the components or blocks of components with the required functionality and import them directly to the embedded motherboard design; the shielding function being included by default. The conventional situation on the other hand has every design and configuration of components designed uniquely relating to shielding. Each block can be independently verified and certified before inclusion into the motherboard or large module.

The present invention provides the advantage that the Radio Frequency knowledge level of the mobile terminal designer can be lowered. RF knowledge can be focused on model creation. Efficient re-use of shielded component, or block, models can be used. The present invention can be directed towards “Plug & Play” use of sensitive components, or blocks, in the embedded motherboard. Potential in-house mobile terminal manufacturer, pre-approval verification for these blocks can be provided before being sent to the system manufacturer or IC vendor.

The absence of Supra-shielding on the RF parts of a competitors product will indicate the use of embedded shielding. In addition, the re-use of components, or blocks, with the same embedded shielding layout by a competitor would indicate the use of a Shielded Embedded Component Library.

A designer of a terminal, where the components were embedded in the motherboard, would merely select the components or blocks of components with the required functionality and import them directly to the embedded motherboard design, the shielding function being included by default. This invention discloses potentially utilizing a copper area which exists between the die and laminate and utilizes this as part of the IC shield.

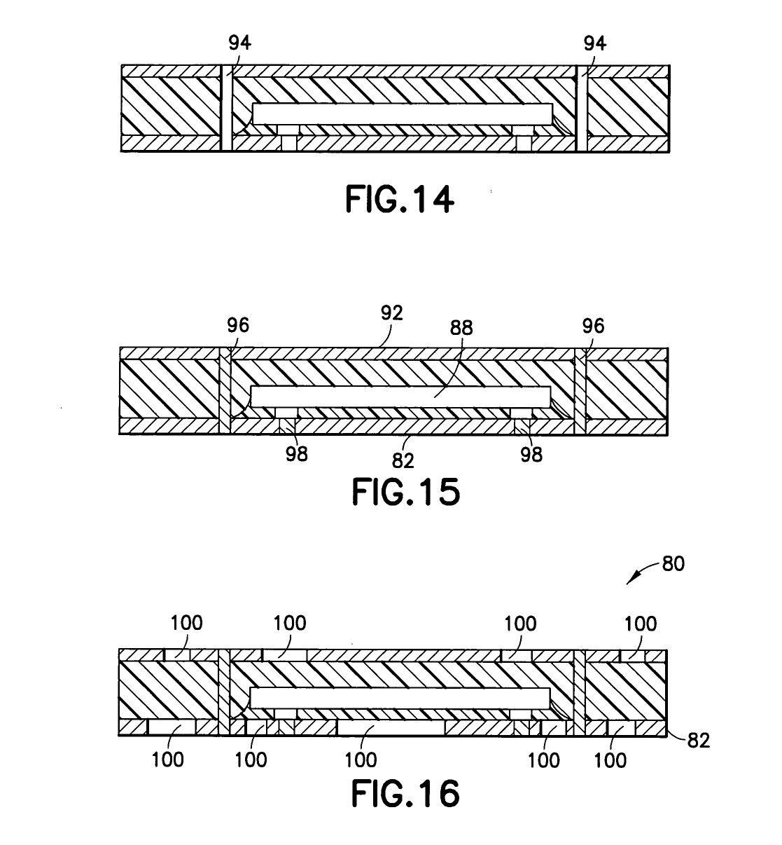

Referring now to FIGS. 10-16, another method for manufacturing an electronic assembly 80 (see FIG. 16) comprising features of the present invention will be described. As seen in FIGS. 10 and 11, the method can start with a metallic foil 82, such as copper for example, and through holes 84 can be formed, such as with a laser for example. As seen in FIG. 12, non-conductive adhesive 86, such as a paste or film for example, can be used to attach the semiconductor die 88 by bonding with heat and pressure. Organic laminate material layers 90 and a metal layer 92 can be staked and pressed with a vacuum and heat and pressure as seen in FIG. 13. The laminate material of the layers 90 can creep up to and surround the die. Microvia cleaning from adhesive residues can be done, such as with a laser or plasma. As seen in FIG. 14, microvia channels can be formed and, as seen in FIG. 15, microvia metallization can form conductive paths 96 and 98. The paths 96 can combine with the layers 82 and 92 to form a shield for the die 88. Core layer patterning can then be done as shown in FIG. 16, such as by copper etching, to form open areas 100. This embodiment illustrates that the present invention can be used without the use of a molded material and without the use of a molding process. Features of the present invention can also be used for whole electronic assemblies rather than modules.

It should be understood that the foregoing description is only illustrative of the invention. Various alternatives and modifications can be devised by those skilled in the art without departing from the invention. Accordingly, the present invention is intended to embrace all such alternatives, modifications and variances which fall within the scope of the appended claims.

What is claimed is:

1. An electronic assembly comprising:
a substrate;
a semiconductor die; and
a shield mounted to the semiconductor die and located, at least partially, between the semiconductor die and the substrate.

2. An electronic assembly as in claim 1 wherein the substrate comprises a motherboard.

3. An electronic assembly as in claim 1 wherein the substrate comprises a module printed circuit board.

4. An electronic assembly as in claim 1 wherein the shield and the semiconductor die are mounted, at least partially, in an aperture in the substrate.

5. An electronic assembly as in claim 1 wherein the shield and the semiconductor die are mounted on an exterior surface of the substrate.

6. An electronic assembly as in claim 1 wherein the shield is mounted to the semiconductor die with an insulator between the semiconductor die and the shield.

7. A method of assembling an electronic assembly comprising:
connecting a shield to a semiconductor die;
connecting the semiconductor die to a substrate,
wherein at least a portion of the shield is located between the semiconductor die and the substrate.

8. A method of assembling an electronic assembly as in claim 7 wherein connecting the semiconductor die to the substrate comprises inserting the semiconductor die into an aperture in the substrate.

9. A method of assembling an electronic assembly as in claim 8 wherein the semiconductor die is substantially entirely embedded in the substrate.

10. A method of assembling an electronic assembly as in claim 7 wherein connecting the semiconductor die to the substrate comprises mounting the semiconductor die to an exterior surface of the substrate.

11. A method of assembling an electronic assembly as in claim 7 further comprising molding a cover onto the substrate and the semiconductor die.

12. A method of assembling an electronic assembly as in claim 7 further comprising connecting fusible elements to contacts on the substrate.

13. A method of assembling an electronic assembly as in claim 7 wherein the shield is connected to the semiconductor die before the semiconductor die is connected to the substrate.

14. A method of assembling an electronic assembly as in claim 7 wherein connecting the shield to the semiconductor die comprises providing an insulator between the semiconductor die and the shield.

15. A method of assembling an electronic assembly comprising:
selecting a first electronic component assembly from a plurality of different electronic component assemblies, the first electronic component assembly comprising a semiconductor die with an attached shield; and
connecting the selected first electronic component assembly to a substrate to form the electronic assembly,
wherein the electronic assembly is formed with the shield already attached to the semiconductor die without having to attached the shield to the semiconductor die or substrate after the semiconductor die is attached to the substrate.

16. A method of assembling an electronic assembly as in claim 15 wherein connecting the selected first electronic component assembly to the substrate comprises inserting the semiconductor die in an aperture in the substrate.

17. A method of assembling an electronic assembly as in claim 16 further comprising locating a least a portion of the shield in the aperture.

18. A method of assembling an electronic assembly as in claim 15 wherein connecting the selected first electronic component assembly to the substrate comprises mounting the semiconductor die on an exterior surface of the substrate.

19. A method of assembling an electronic assembly as in claim 15 further comprising molding a cover onto the substrate and the semiconductor die, and connecting fusible elements to contacts on the substrate.

20. A method of assembling an electronic assembly as in claim 15 wherein the shield is formed by inserting a semiconductor die into a laminate which has metal connection paths, wherein the metal connection paths are form at least a portion of the shield.

21. An electronic component assembly comprising:
a semiconductor die; and
a shield fixedly connected to the semiconductor die,
wherein the electronic component assembly is sized and shaped to be at least partially mounted in a receiving area of a substrate with at least a portion of the shield being located between the semiconductor die and the substrate.

22. A printed circuit board assembly comprising:
a substrate; and
an electronic component assembly as in claim 21 embedded in an aperture of the substrate.

23. An electronic module comprising:
a substrate;
an electronic component assembly as in claim 21 embedded in an aperture of the substrate; and
fusible elements on the substrate and electrically coupled to the semiconductor die.
